(19) United States
(12) Patent Application Publication
(10) Pub. No.: US 2001/0055220 A1
(43) Pub. Date: Dec. 27, 2001

(54) Voltage regulation device for reference cell of a dynamic random access memory, reference cell, memory and associated process

(75) Inventor: Richard Ferrant, Saint Ismier (FR)

Correspondence Address: ALLEN, DYER, DOPPELT, MILBRATH & GILCHRIST P.A., 1401 CITRUS CENTER 255 SOUTH ORANGE AVENUE, P.O. BOX 3791, ORLANDO, FL, 32802-3791, US

(73) Assignee: STMicroelectronics S.A., Montrouge (FR)

(21) Appl. No.: 09/853,254

(22) Filed: May 11, 2001

(30) Foreign Application Priority Data
Jun. 13, 2000 (FR) 0007521

(51) Int. Cl. G11C 11/24; H03H 11/26

(52) U.S. Cl. 365/149; 327/264; 327/283

(57) ABSTRACT

A voltage regulation device is for a reference cell of a dynamic random access memory arranged in lines and columns and including a plurality of memory cells. The device includes at least one capacitor of a predetermined capacitance which can be discharged during memory access.

### FIELD OF THE INVENTION

The invention relates to the field of electronic circuits, and, more particularly, to memory cells or memory slots of a dynamic random access memory (DRAM).

### BACKGROUND OF THE INVENTION

In static random access memories (SRAM), information stored therein remains stored indefinitely, i.e., for at least as long as the memory remains energized. On the other hand, dynamic memories require periodic refreshing of the information stored therein due, in particular, to the stray leakage currents which discharge the storage capacitor of each memory slot.

Conventionally, dynamic random access memories are arranged in lines and columns of memory cells and include an amplification device for each column for reading/rewriting each memory cell selected. This device includes precharge means for precharging the corresponding column of the matrix (commonly referred to as a “bit line” by those skilled in the art) to a chosen voltage level and amplification means comprising, for example, two looped-back inverters forming a bistable flip-flop. Each of the looped-back inverters is formed by two complementary transistors and controlled by two successive read and rewrite signals.

The majority of dynamic memories include reference cells which make it possible to equalize the charges in the bit lines and to maximize the mean amplitude of the signal between logic 0 and logic 1. The reference cells generally include a connection or port connected to the bit line and another connection or port connected to a reference voltage. Use of reference cells having the same capacitance as the memory cell makes it possible to obtain the same capacitance at each node during access to a line. The value of the voltage stored in the reference cell is equal to half the reference voltage. To obtain the same margin of variation for the two binary logic 0 and logic 1 values, the reference must be adjusted to the mid-point, i.e., to half the reference voltage. A voltage equal to half the reference value must therefore be precharged in the reference cell between two line accesses.

Generally, a voltage generator provided with active components is used. Such a generator must be relatively fast. Otherwise, the duration of the precharge will have an effect on performance, i.e., the generator is large and consumes a lot of current even when not in use. Adjusting such a generator is usually impossible since satisfactory accuracy is only achieved over a small voltage range. The present invention is directed to a device and related method which alleviate these drawbacks.

### SUMMARY OF THE INVENTION

The invention relates to a device and related method for providing a suitable voltage to a reference cell which is economic, multifunctional, and has a low energy consumption.

The device according to one aspect of the invention regulates the voltage of a reference cell of a dynamic random access memory including a plurality of memory cells arranged in lines and columns. The device includes at least one capacitor of a predetermined capacitance which can be discharged during memory access. Preferably, the capacitor can be completely discharged during memory access.

More specifically, the capacitance of the capacitor may be equal to C_{cell}*(V_{ref}−_{Vrci})/V_{rci}, where C_{cell} is the capacitance of the reference cell, V_{rcf} is the voltage of the reference cell after memory access, and V_{rci} is the voltage of the reference cell before memory access. The device may include a first interrupter placed at the input of the capacitor to control charging of the capacitor, where a charging current may be provided from the reference cell. In this way, it is possible to accurately obtain a known voltage on the reference cell. Furthermore, the device includes a second interrupter placed at the output of the capacitor to control discharging of the capacitor. The voltage at the terminals of the capacitor can be reset to zero. Preferably, the device includes a plurality of existing capacitors on an integrated circuit.

Advantageously, the device may share at least one capacitor with at least one other similar device. Additionally, several devices may share a certain number of capacitors. The reference cell is particularly well suited for a dynamic random access memory, for example. Preferably, the reference cell includes a first port which can be connected to a memory cell and a second port connected to the regulating device. A memory according to the invention may include a reference cell as set forth above.

A method according to the invention is for regulating the voltage of a reference cell for a dynamic random access memory including a plurality of memory cells arranged in lines and columns. Charge is shared between at least two capacitors of predetermined capacitances during an initialization step, and one of the two capacitors is discharged during memory access. Thus, the capacitor is charged during charge sharing and discharged during memory access. Preferably, the charge to be shared comes from a capacitor of the reference cell.

One or more existing capacitors of an integrated circuit may be used. Also, n capacitors may be used to regulate the voltage of p reference cells, where n is different from p. Each reference cell benefits from a capacitance equal to the sum of the capacitances divided by p. If the capacitances have equal values C_{cal}, each reference cell benefits from a capacitance of C_{cal}×n/p. In this way, a reference voltage is generated which is well suited to the reference cells, only a small area of silicon is required, and power consumption is virtually zero.

### BRIEF DESCRIPTION OF THE DRAWINGS

An embodiment of the invention is illustrated in the appended drawings, in which:

FIG. 1 is a schematic diagram of a reference cell and a voltage regulation device according to the invention; and

FIG. 2 is a schematic view of a memory cell including a reference cell according to the invention.

### DETAILED DESCRIPTION OF THE PREFERRED EMBODIMENTS

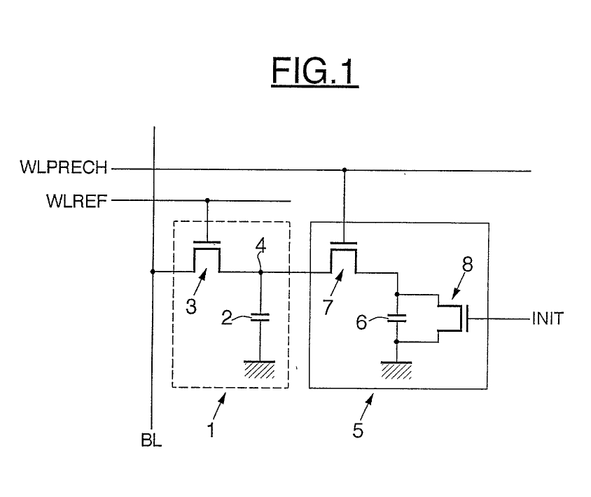

Turning now to FIG. 1, a reference cell 1 according to the invention is shown. For simplification, only a single reference cell 1 is shown. The reference cell 1 includes a storage capacitor 2 and a transistor 3, for example, of the metal-oxide semiconductor (MOS) type. The control input of the transistor 3 is connected to a word line receiving a signal WLREF. One of the other two terminals of the transistor 3 is connected to a bit line BL, and the other is connected to the capacitor 2. The other terminal of the capacitor 2 is connected to the ground of the circuit. A common point 4 is between the transistor 3 and the capacitor 2. More generally, it will be understood that the circuit comprises one reference cell 1 per bit line BL.

A device 5 for regulating the charging voltage of the capacitor 2 of the reference cell 1 includes a capacitor 6. One terminal of the capacitor 6 is connected to the ground of the circuit. Further, the device 5 includes a transistor 7 (e.g., a MOS transistor) having one terminal connected to the other terminal of the capacitor 6 and the other terminal connected to the point 4 of the reference cell 1. The control input of the transistor 7 is connected to a word line receiving a signal WLPRECH. The device 5 also includes a transistor 8 (e.g., a MOS transistor) mounted in parallel with the capacitor 6. The control input of the transistor 8 receives a signal INIT.

The regulation device 5 and the memory cell 1 operate as follows. The reference cell 1 maintains a voltage on the bit line BL. For a circuit supply voltage V_{dd}, it is possible for the reference cell to maintain a voltage of V_{dd}/2 on the bit line BL. Advantageously, to increase the reliability of operation of the circuit, it may be possible to maintain a lesser voltage, for example, equal to V_{dd}/3. It follows that a voltage less than V_{dd}/3 is considered a logic level 0 and that a voltage greater than V_{dd}/3 is considered a logic value 1, the voltage equal to V_{dd}×⅔ being the nominal logic level 1. Thus, the voltage present on the bit line BL may go down from V_{dd} to V_{dd}×⅔ without any significant problem.

The reference cell must therefore be precharged to a voltage value of V_{dd}/3 between two line accesses. The term C_{cell} is the capacitance of the capacitor 2 and C_{bl} is the capacitance of the bit line BL. Memory operation is based on sharing charges between the bit line BL and the reference cell 1. The capacitances C_{bl} and C_{cell} are accurately known. The bit line BL is precharged to a voltage between V_{dd}/2 and V_{dd}. Charge sharing occurs between the bit line BL and the reference cell 1 which is seen as a voltage decrease on the bit line BL and a voltage increase in the reference cell 1 according to the following equation: V_{blf}=V_{rcf}=C_{bl}/(C_{bl}+C_{cell})×V_{bli}+C_{cell}/(C_{cell}+C_{bl})×V_{rci}, where V_{blf} is the final voltage of the bit line BL, V_{rcf} is the final voltage of the reference cell 1, V_{bli} is the initial voltage of the bit line BL, and V_{rci} is the initial voltage of the reference cell 1.

For acceptable operation, the reference cell 1 should return to the voltage V_{rci} for the next access, i.e., before the signal WLREF turns on the transistor 3 of the reference cell 1. By virtue of the regulation device 5, the point 4 forming the second port of the reference cell 1 is connected to the capacitor 6. A capacitance C_{cal} of the capacitor 6 is determined accurately, and this capacitor may be completely discharged during access.

In other words, the transistors 3 and 8 are turned on at substantially the same time, while the transistor 7 is blocked. At a time where the transistors 3 and 8 are blocked, the transistor 7 may be turned on so that the charges can be shared between the capacitors 2 and 6. This charge sharing is governed by the following equation: V_{rcp}=V_{rci}=C_{cell}/(C_{cell}+C_{cal})×V_{rcf}+C_{cal}/(C_{cell}+C_{cal})×0, where V_{rcp} is the voltage of the reference cell 1, i.e., the voltage between the point 4 and the ground of the circuit after this second charge sharing (i.e., after the signal WLPRECH has turned on the transistor 7). From the above equation, it can be deduced that: C_{cal}=C_{cell}×(V_{rcf}−V_{rci})/V_{rci}. Now, all terms on the right of this equation are known accurately, therefore the capacitance C_{cal} can be calculated.

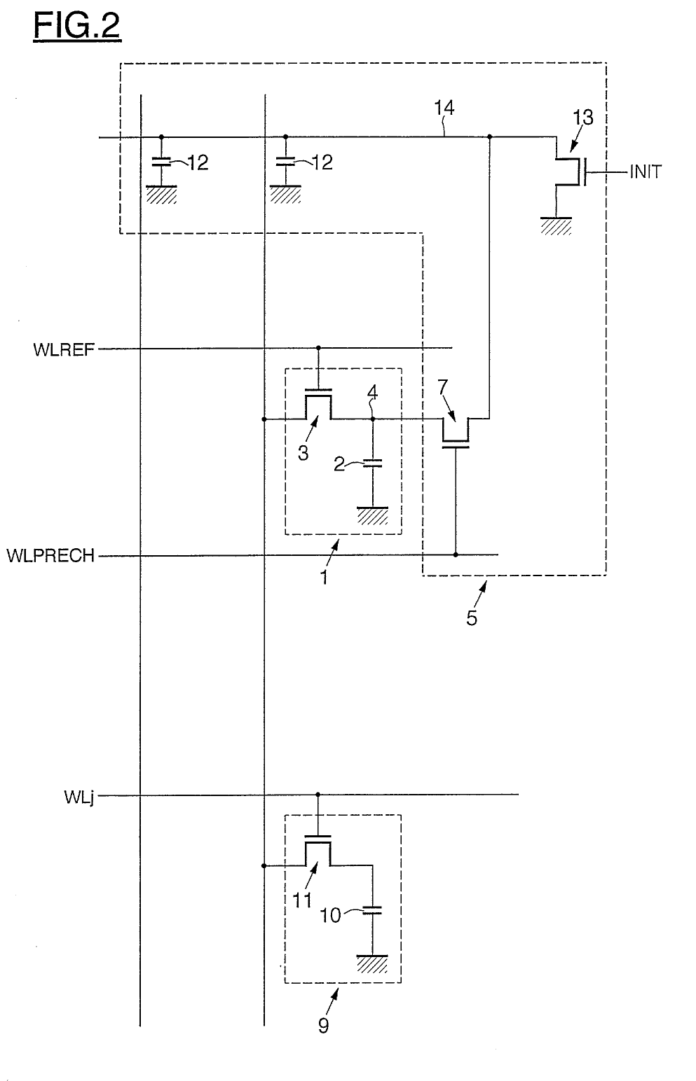

A bit line BLi belonging to a memory comprising a plurality of bit lines may be seen in FIG. 2. A memory cell 9 has been shown connected to the bit line BLₗ and also connected to a word line WLⱼ. The memory cell 9 includes a capacitor 10 and a transistor 11 (e.g., a MOS transistor). The transistor 11 and the capacitor 10 are arranged in series between the bit line BLₗ and the ground of the circuit. The control input of the transistor 11 is connected to the word line WLⱼ. A reference cell 1 is connected on the bit line BLᵢ, to which a plurality of memory cells similar to the cell 9 are connected. In other words, one reference cell 1 per bit line BL is provided.

The regulation device 5 is provided according to the same principle as in the previous embodiment but is slightly different in that it shares a plurality of capacitors 12 and a transistor 13 with other regulation devices for other bit lines BLₖ, where k is different from i. That is, a transistor 7 is connected by one terminal to each reference cell 1, by its control terminal to the word line WLPRECH, and by its other terminal to a line 14. A plurality of capacitors 12 are also each connected by one terminal to the line 14 and by the other terminal to the ground of the circuit. The capacitors 12 are set to zero by a transistor 13 mounted in parallel therewith. Thus, a single transistor 13 is able to discharge a plurality of capacitors 12.

This embodiment is beneficial in the sense that the capacitance C_{cal}, which it is desired to obtain, may turn out to be less than C_{cell} or even less than 25% of C_{cell}, which is the smallest capacitance that can be achieved with appropriate accuracy. Thus, by making a number n of capacitors common between a number p of reference cells 1, a capacitor with a total capacitance of n×C_{cal} is obtained. Yet, the charge of this capacitor is distributed over p reference cells 1 passing through p transistors 7 so that the charge provided to a reference cell 1 is equal to the charge provided by a single capacitor of capacitance C_{cal}. This is simulated by making available to each reference cell 1 a charge corresponding to a capacitor of n/p times the capacitance of a capacitor 12.

In general, the capacitors 12 have a capacitance of C_{cell} since this is the minimum that it is possible to obtain with appropriate accuracy. Thus, there is the advantage of a reference cell 1 with a capacitance C_{cal}=n/p×C_{cell}. In addition, by making the capacitors 12 common between several reference cells, the transistor 13 is also made common, which makes it possible to reduce the number of active components in the circuit.

Moreover, integrated circuits, especially memories, generally include a row of capacitors of capacitance C_{cell} arranged in a line at one end of the circuit that are not used. These unused capacitors can therefore be used as voltage regulation capacitors for the reference cells.

In the embodiment of FIG. 2 where the number n of capacitors needed is less than the number p of associated reference cells 1, n capacitors placed at one end of the circuit will be used and the remaining p−n capacitors will remain unused. Using these capacitors at the end of the circuit does not greatly change the fabrication process. The connection can be made by changing a single mask.

The invention is applicable particularly to integrated circuits whose etching width is small and for which voltage generators are difficult to produce. The invention is therefore advantageously applicable to circuits of 0.18 microns, 0.12 microns, and 0.09 microns width, for example, and to even smaller widths. In addition, the consumption of a device for regulating the voltage of the reference cells according to the invention is extremely small and, in any case, is less than that of a voltage generator. In practice, between one fifth and one third of the circuit end capacitors will be used. By way of example, 27% of these capacitors may be used.

By assuming an initial state where all the signals on the word lines are inactive, the memory is accessed when the signal WL, is active. Simultaneously, the signal WLREF is activated to maintain a satisfactory voltage on the bit line BL, and the signal INIT to discharge the capacitor 6 of FIG. 1 or the capacitors 12 of FIG. 2. After returning to the inactive state of these various signals, the signal WLPRECH is activated which turns on the transistor 7 and allows a decrease of the voltage of the reference cells 1 by passing charges to the capacitor 6 or the capacitors 12. After a predetermined time, the signal WLPRECH is returned to the inactive state.

That which is claimed is:

1. Voltage regulation device (5) for reference cell (1) of a dynamic random access memory laid out in lines and in columns, comprising a plurality of memory cells, characterized in that it comprises at least one capacitor (6) of predetermined capacitance which can be discharged during memory access.

2. Device according to claim 1, characterized in that the capacitance of the said capacitor is equal to: C_{cell}*(V_{ref}−V_{rci})/V_{rci} where C_{cell} is the capacitance of the reference cell, V_{rcf} is the voltage of the reference cell after memory access and V_{rci} is the voltage of the reference cell before memory access.

3. Device according to claim 1 or 2, characterized in that it comprises a first interrupter (7) placed at the input of the said capacitor to control charging of the said capacitor, it being possible for a charging current to come from a reference cell.

4. Device according to any one of the preceding claims, characterized in that it comprises a second interrupter (8) placed at the output of the said capacitor (6) in order to control discharging of the said capacitor.

5. Device according to any one of the preceding claims, characterized in that it shares at least one capacitor (12) with at least one other similar device.

6. Reference cell (1) for dynamic random access memory, characterized in that it comprises a device according to any one of the preceding claims.

7. Cell according to claim 6, characterized in that it comprises a first port which can be connected to a memory cell and a second port connected to the regulation device.

8. Memory, characterized in that it comprises a cell according to either of claims 6 and 7.

9. Process for regulating the voltage of a reference cell for a dynamic random access memory laid out in lines and in columns, comprising a plurality of memory cells, in which charge is shared between at least two capacitors of predetermined capacitances during an initialization step and one of the two capacitors is discharged during memory access.

10. Process according to claim 9, in which the charge to be shared comes from a capacitor of a reference cell.

11. Process according to claim 9 or 10, in which one or more existing capacitors of an integrated circuit are used.

12. Process according to claim 9, 10 or 11, in which n capacitors are used to regulate the voltage of p reference cells, where n is different to p.
